(19) United States
(12) Patent Application Publication
(10) Pub. No.: US 2025/0351656 A1
(43) Pub. Date: Nov. 13, 2025

(54) ELECTRONIC DEVICE AND MANUFACTURING METHOD THEREOF

(71) Applicant: InnoLux Corporation, Miao-Li County (TW)

(72) Inventors: Wei-Ju LIAO, Miao-Li County (TW); Yu-Tsung LIU, Miao-Li County (TW); Yu-Ting TSAI, Miao-Li County (TW); I-An YAO, Miao-Li County (TW)

(21) Appl. No.: 19/174,364

(22) Filed: Apr. 9, 2025

(30) Foreign Application Priority Data
May 9, 2024 (CN) 202410567370.7

(51) Int. Cl. H10H 29/85; H01L 25/075; H10H 29/01; H10H 29/855

(52) U.S. Cl. CPC H10H 29/857; H01L 25/0753; H10H 29/0363; H10H 29/0364; H10H 29/855

(57) ABSTRACT

A manufacturing method of electronic device includes: (a) providing a circuit substrate including: a substrate; a plurality of electronic units disposed on the substrate; and a first bonding member disposed on the substrate, wherein the first bonding member surrounds the electronic units; (b) respectively disposing a plurality of cover plates on at least part of the electronic units, and disposing a bonding material on the first bonding member, wherein one of the cover plates includes a second bonding member and, in the top view direction of the circuit substrate, the second bonding member overlaps at least part of the first bonding member, and the bonding material does not overlap the second bonding member; and (c) melting the bonding material to allow part of the bonding material to flow in between the first bonding member and the second bonding member.

### CROSS-REFERENCE TO RELATED APPLICATIONS

This application claims the benefits of the Chinese Patent Application Serial Number 202410567370.7, filed on May 9, 2024, the subject matter of which is incorporated herein by reference.

### BACKGROUND

### Field of the Disclosure

The present disclosure relates to an electronic device and a manufacturing method thereof and, more particularly, to an electronic device including a cover plate and a manufacturing method thereof.

### Description of Related Art

In general, during the manufacturing process of electronic devices, such as during the packaging process, the cover plate and the circuit substrate are assembled and then cut to form a plurality of independent electronic units. In the prior manufacturing process, bonding materials are often used to achieve the assembly step of the cover plate and the circuit substrate.

However, in the prior manufacturing process, the bonding material is still prone to overflow or squeeze out of the bonding position. As a result, the bonding material may flow into the sealed space, causing the function of the electronic unit to be affected and the operation to be poor, or the vacuum degree after assembly to be insufficient, or the situation of material waste due to abnormal packaging of electronic units.

Therefore, there is an urgent need to provide an electronic device and a manufacturing method thereof so as to alleviate and/or obviate the aforementioned defects.

### SUMMARY

The present disclosure provides a manufacturing method of an electronic device, which includes the steps of: (a) providing a circuit substrate, which includes: a substrate; a plurality of electronic units disposed on the substrate; and a first bonding member disposed on the substrate, wherein, in a top view direction of the circuit substrate, the first bonding member surrounds the electronic units; (b) respectively disposing a plurality of cover plates on at least part of the electronic units, and disposing a bonding material on the first bonding member, wherein one of the cover plates includes a second bonding member and, in the top view direction of the circuit substrate, the second bonding member overlaps at least part of the first bonding member, and the bonding material does not overlap the second bonding member; and (c) melting the bonding material to allow part of the bonding material to flow in between the first bonding member and the second bonding member.

The present disclosure further provides an electronic device, which includes: a circuit substrate including: a substrate; an electronic unit disposed on the substrate; and a first bonding member disposed on the substrate and surrounding the electronic unit; a cover plate disposed on the first bonding member, wherein the cover plate includes a second bonding member and, in a top view direction of the circuit substrate, the cover plate overlaps the electronic unit, and the second bonding member overlaps at least part of the first bonding member; and a bonding material including a first portion and a second portion, the first portion being disposed between the first bonding member and the second bonding member, the second portion being disposed on the first bonding member, wherein, in the top view direction of the circuit substrate, the second portion does not overlap the second bonding member, wherein a thickness of the first portion is smaller than a thickness of the second portion of the bonding material.

Other novel features of the disclosure will become more apparent from the following detailed description when taken in conjunction with the accompanying drawings.

### BRIEF DESCRIPTION OF DRAWINGS

FIG. 1 is a flow chart of a manufacturing method of an electronic device according to an embodiment of the present disclosure;

FIG. 2A, FIG. 2B-1, FIG. 2B-2, FIG. 2C, FIG. 2D, FIG. 2E and FIG. 2F are schematic diagrams illustrating a manufacturing method of an electronic device according to an embodiment of the present disclosure;

FIG. 3A to FIG. 3F are schematic diagrams illustrating a manufacturing method of an electronic device according to another embodiment of the present disclosure;

FIG. 4 is a schematic cross-sectional view of an electronic device according to an embodiment of the present disclosure;

FIG. 5A and FIG. 5B are enlarged schematic diagrams of part of an electronic device according to an embodiment of the present disclosure;

FIG. 6 is a schematic diagram of an electronic unit according to an embodiment of the present disclosure;

FIG. 7A and FIG. 7B are schematic diagrams illustrating a manufacturing method of an electronic device according to an embodiment of the present disclosure; and

FIG. 8 is a schematic cross-sectional view of an electronic device according to an embodiment of the present disclosure.

### DETAILED DESCRIPTION OF EMBODIMENT

The implementation of the present disclosure is illustrated by specific embodiments to enable persons skilled in the art to easily understand the other advantages and effects of the present disclosure by referring to the disclosure contained therein. The present disclosure is implemented or applied by other different, specific embodiments. Various modifications and changes can be made in accordance with different viewpoints and applications to details disclosed herein without departing from the spirit of the present disclosure.

It should be noted that, in the specification and claims, unless otherwise specified, having “one” element is not limited to having a single said element, but one or more said elements may be provided. In addition, in the specification and claims, unless otherwise specified, ordinal numbers, such as “first” and “second”, used herein are intended to distinguish components rather than disclose explicitly or implicitly that names of the components bear the wording of the ordinal numbers. The ordinal numbers do not imply what order a component and another component are in terms of space, time or steps of a manufacturing method. A “first” element and a “second” element may appear together in the same component, or separately in different components. The existence of an element with a larger ordinal number does not necessarily mean the existence of another element with a smaller ordinal number.

In the entire specification and appended claims of the present disclosure, certain words are used to refer to specific components. Those skilled in the art should understand that electronic device manufacturers may refer to the same components by different names. The present disclosure does not intend to distinguish those components with the same function but different names. In the following description and claims, words such as “comprising”, “including”, and “having” are open type words, so they should be interpreted as meaning “including but not limited to . . . ”. Therefore, when the terms “comprising”, “including” and/or “having” are used in the description of the present disclosure, they specify the existence of corresponding features, regions, steps, operations and/or components, but do not exclude the existence of one or more corresponding features, regions, steps, operations and/or components.

In the description, the terms “almost”, “about”, “approximately” or “substantially” usually means within 10%, 5%, 3%, 2%, 1% or 0.5% of a given value or range. The quantity given here is an approximate quantity; that is, without specifying “almost”, “about”, “approximately” or “substantially”, it can still imply the meaning of “almost”, “about”, “approximately” or “substantially”. In addition, the term “range of the first value to the second value” or “range between the first value and the second value” indicates that the range includes the first value, the second value, and other values in between the first value and the second value.

Unless otherwise defined, all terms (including technical and scientific terms) used here have the same meanings as commonly understood by those skilled in the art of the present disclosure. It is understandable that these terms, such as those defined in commonly used dictionaries, should be interpreted as having a meaning consistent with the relevant technology and the background or context of the present disclosure, rather than in an idealized or excessively formal interpretation, unless specifically defined.

In addition, relative terms such as “below” or “bottom”, and “above” or “top” may be used in the embodiments to describe the relationship between one component and another component in the drawing. It can be understood that, if the device in the drawing is turned upside down, the components described on the “lower” side will become the components on the “upper” side. When the corresponding member (such as a film or region) is described as “on another member”, it may be directly on the other member, or there may be other members between the two members. On the other hand, when a member is described as “directly on another member”, there is no member between the two members. In addition, when a member is described as “on another member”, the two members have a vertical relationship in the top view direction, and this member may be above or below the other member, while the vertical relationship depends on the orientation of the device.

In the present disclosure, the distance, width, length and thickness may be measured by using an optical microscope, and the distance, width, length and thickness may be measured by the cross-sectional image in an electron microscope, but it is not limited thereto. In addition, there may be a certain error in any two values or directions used for comparison. If the first value is equal to the second value, it implies that there may be an error of about 10% between the first value and the second value. If the first direction is perpendicular to the second direction, the angle between the first direction and the second direction may be 80 to 100 degrees. If the first direction is parallel to the second direction, the angle between the first direction and the second direction may be 0 to 10 degrees.

It should be noted that the technical solutions provided by the different embodiments below can be replaced, combined or used in combination, so as to constitute another embodiment without violating the spirit of the present disclosure.

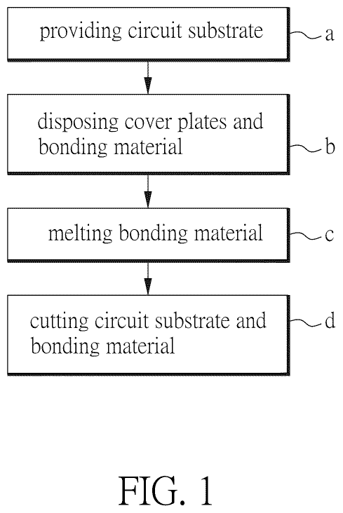

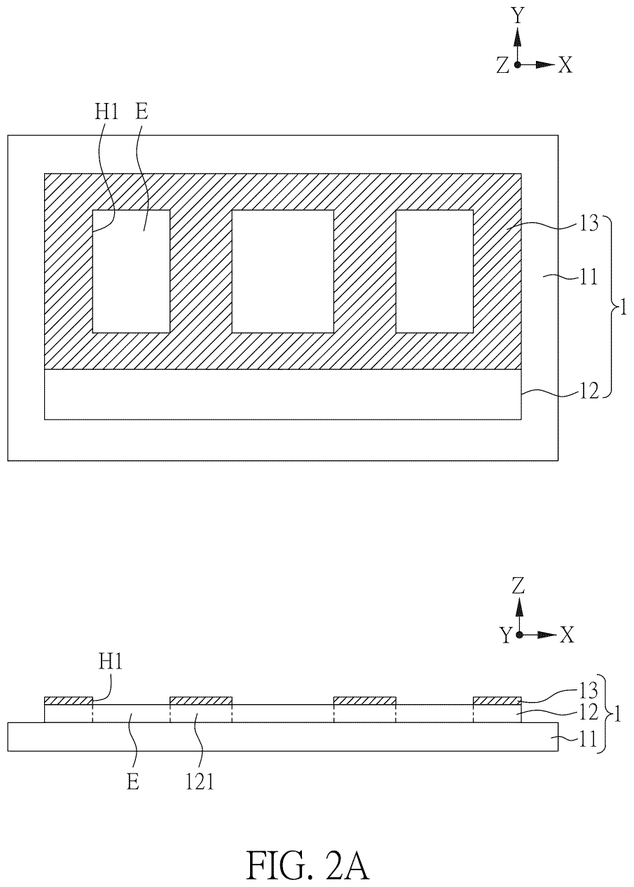

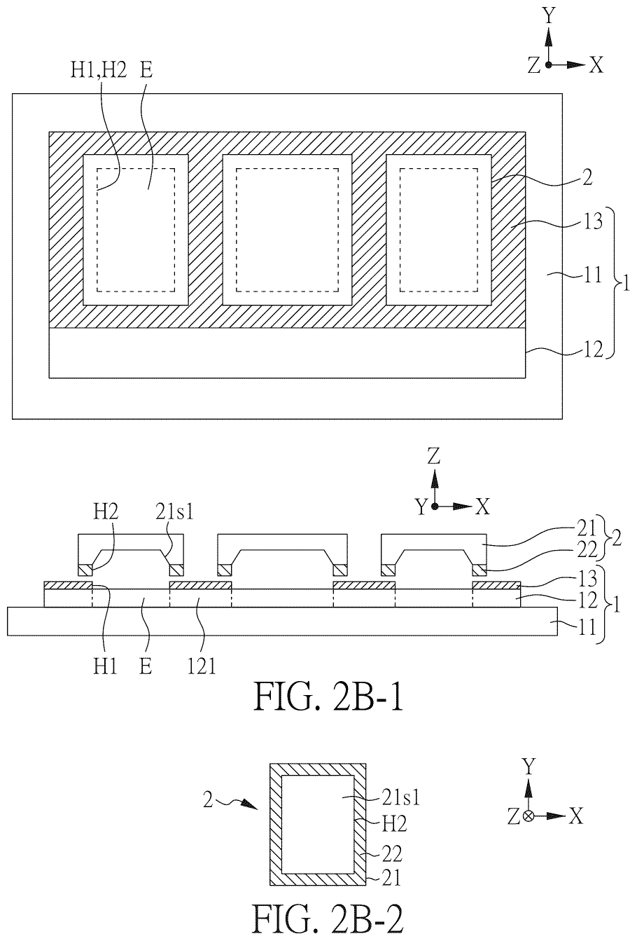

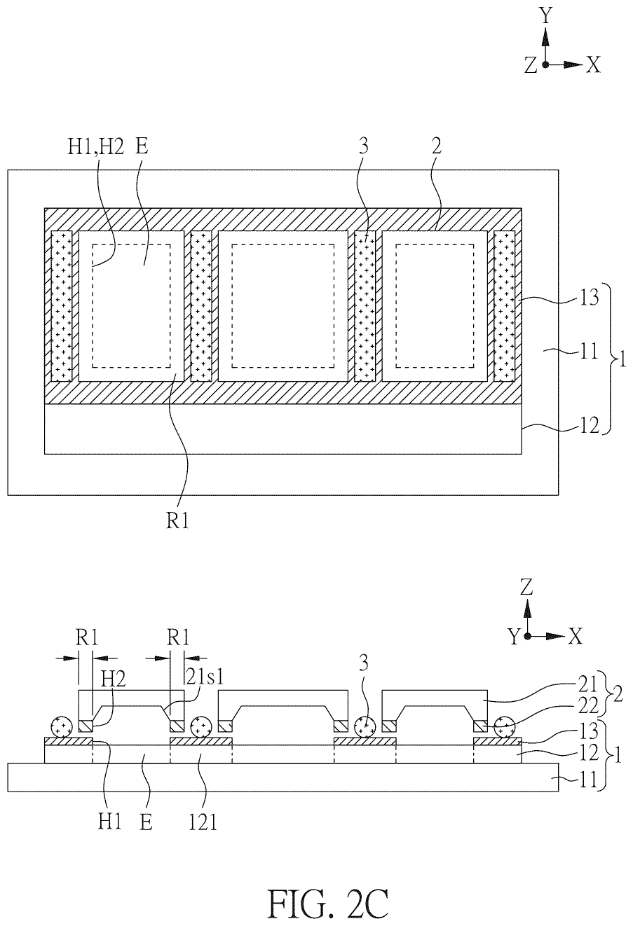

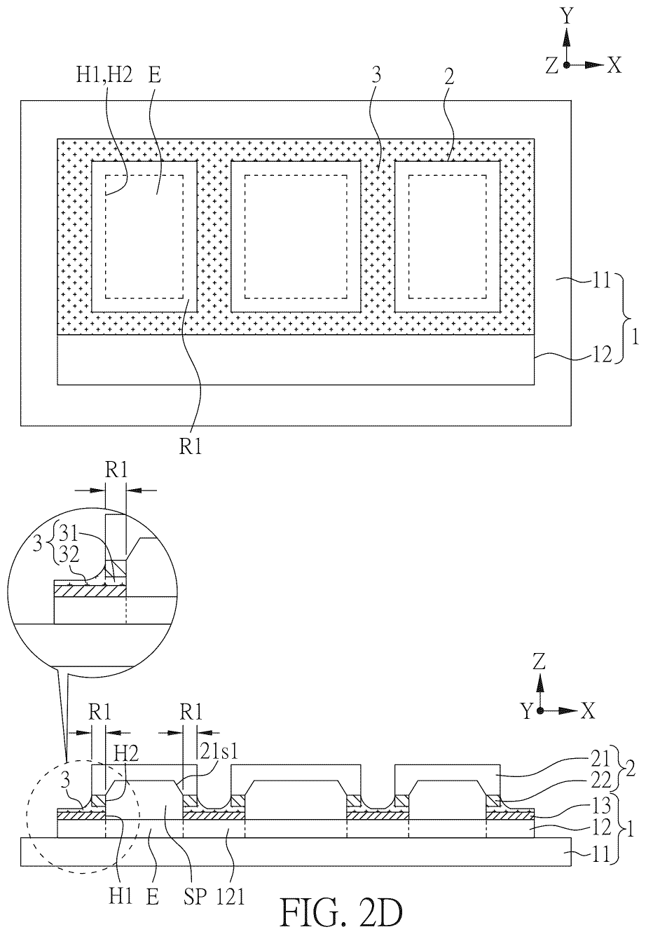

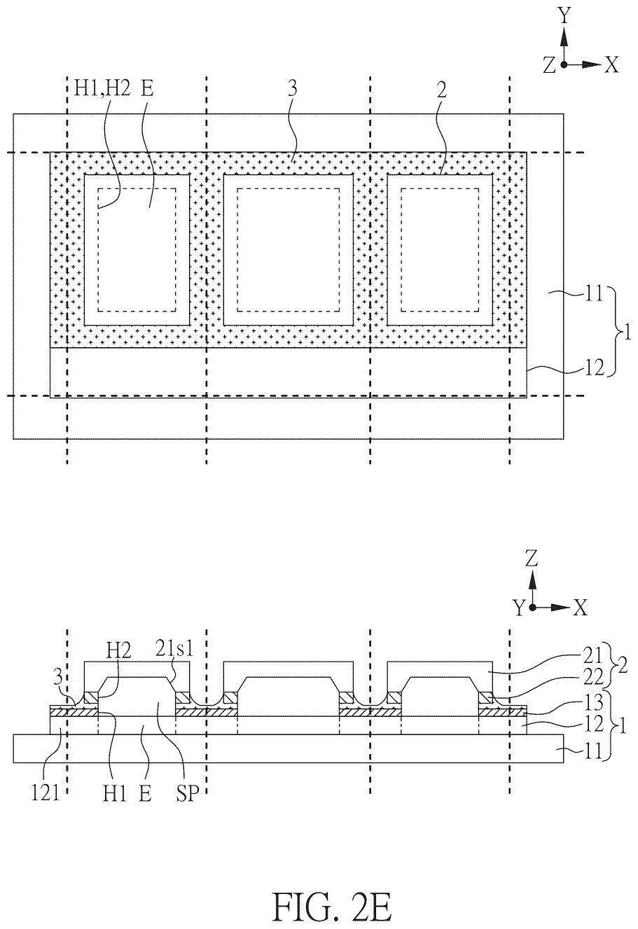

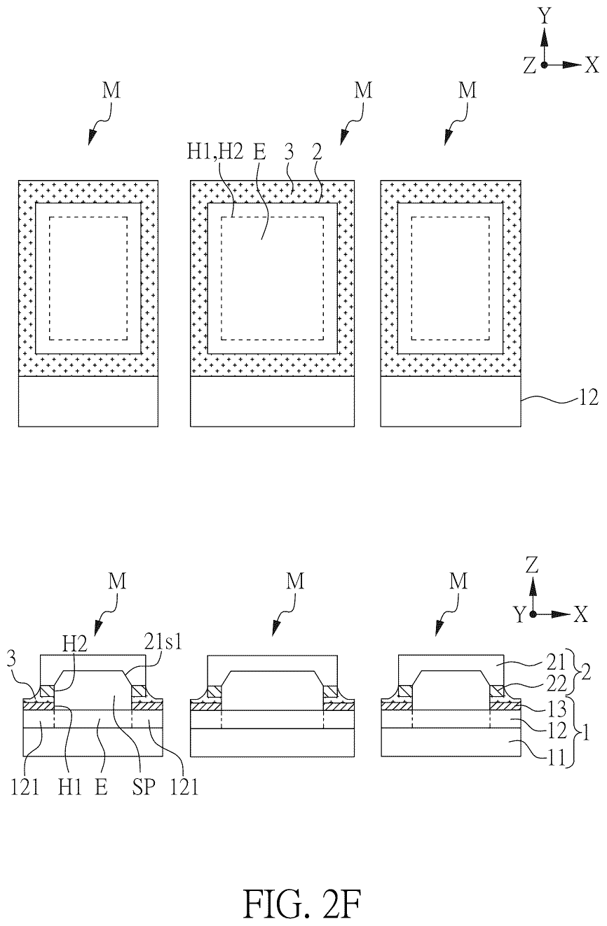

The electronic device of the present disclosure may include, for example, a display device, a sensing device, an antenna device, a touch device, a tilted device or other suitable electronic devices, but not limited thereto. The display device of the present disclosure may be a non-self-luminous display device or a self-luminous display device, such as a liquid crystal display, a cholesteric liquid crystal display, an electrophoretic display, an organic light emitting diode display, a light emitting diode display, but not limited thereto. The display device may include a light emitting diode, a light conversion layer or other suitable materials, or a combination thereof, but not limited thereto. The light emitting diode may include, for example, an organic light emitting diode (OLED), a sub-millimeter light emitting diode (mini LED), a micro light emitting diode (micro LED) or a quantum dot light emitting diode (quantum dot LED, which may include QLED, QDLED), but not limited thereto. The light conversion layer may include wavelength conversion materials and/or filter materials. The light conversion layer may include, for example, fluorescence, phosphorescence, quantum dots, other suitable materials, or a combination thereof, but not limited thereto. The sensing device may include, for example, a biosensor, a touch sensor, a fingerprint sensor, an infrared sensor, a temperature sensor, other suitable sensors, or a combination thereof. The antenna device may be, for example, a liquid crystal antenna or other types of antennas, but not limited thereto. The tilted device may include, for example, a tiled display device or a tiled antenna device, but not limited thereto. The electronic device may include electronic components, and the electronic components may include passive components, active components, or a combination thereof, such as capacitors, resistors, inductors, varactor diodes, variable capacitors, filters, diodes, transistors, sensors, micro-electromechanical system components (MEMS), chips, etc., but not limited thereto. It should be noted that the electronic device of the present disclosure may be various combinations of the above devices, but not limited thereto.

| FIG. 1 is a flow chart of a manufacturing method of an electronic device according to an embodiment of the present disclosure, and FIG. 2A to FIG. 2F are schematic diagrams illustrating a manufacturing method of an electronic device according to an embodiment of the present disclosure, wherein the upper half portions of FIG. 2A to FIG. 2F are schematic top views, and the lower half portions are schematic cross-sectional views. For convenience of explanation, some components are omitted in the schematic diagrams.

In one embodiment of the present disclosure, as shown in FIG. 1 and FIG. 2A, the manufacturing method of an electronic device may include: step (a), in which a circuit substrate 1 is provided. The circuit substrate 1 may include: a substrate 11; a plurality of electronic units E disposed on the substrate 11; and a first bonding member 13 disposed on the substrate 11, wherein the first bonding member 13 includes a plurality of openings H1 and, in the top view direction Z of the circuit substrate 1, the first bonding member 13 surrounds the plurality of electronic units E, and the openings

H1 of the first bonding member 13 expose the electronic units E, respectively.

In more detail, as shown in FIG. 2A, the circuit substrate 1 may include a circuit layer 12, which is disposed on the substrate 11. The circuit layer 12 may include a plurality of electronic units E, wherein the first bonding member 13 is disposed on the circuit layer 12, and the first bonding member 13 may be disposed around the electronic unit E in the top view direction Z of the circuit substrate 1. Therefore, in the top view direction Z of the circuit substrate 1, the projection area of the opening H1 of the first bonding member 13 on the substrate 11 may be substantially equal to the projection area of the electronic unit E on the substrate 11 and, in the top view direction Z of the circuit substrate 1, the opening H1 may expose the electronic unit E. In more detail, as shown in FIG. 2A, the circuit layer 12 may include a plurality of areas. The area exposed by the opening H1 is the electronic unit E, and the area covered by the first bonding member 13 is the connection unit 121, wherein the electronic unit E is surrounded by connection unit 121. The “connection unit” refers, for example, to the portion of the circuit layer 12 that does not have wires, or the portion of the circuit layer 12 that does not have the function of releasing or receiving signals.

In the present disclosure, the material of the substrate 11 may include glass, quartz, sapphire, ceramics, polycarbonate (PC), polyimide (PI), polypropylene (PP), polyethylene terephthalate (PET), polymethylmethacrylate (PMMA), other suitable materials or a combination thereof, but the present disclosure is not limited thereto.

In the present disclosure, the material of the first bonding member 13 may include aluminum, nickel, gold, palladium (Pd), copper, titanium, alloy thereof, or a combination thereof. In the present disclosure, the first bonding member 13 may have a single-layer or multi-layer structure, and each layer may be made of the same or different materials. For example, the first bonding member 13 may have a multi-layer structure of aluminum/nickel/copper, aluminum/nickel/palladium/gold, copper/nickel/gold, copper/gold/palladium/gold or titanium/copper, but the present disclosure is not limited thereto. In the present disclosure, the thickness of the first bonding member 13 may be 0.1 μm to 500 μm, such as 50 μm to 500 μm, but the present disclosure is not limited thereto. When the material of the first bonding member 13 includes gold (Au), the thickness of the gold (Au) layer may be 10 nm to 100 nm or 100 nm to 2000 nm, but the present disclosure is not limited thereto, and the gold layer may be used to provide an excellent bonding effect. When the material of the first bonding member 13 includes palladium (Pd), the thickness of the palladium (Pd) layer may be 10 nm to 500 nm, but the present disclosure is not limited thereto. The palladium layer may be used to prevent the metal materials of the upper and lower layers from diffusing and causing abnormal conditions in the subsequent steps. In the present disclosure, the thickness of the first bonding member 13 refers, for example, to the distance between the side of the first bonding member 13 away from the substrate 11 and the side of the first bonding member 13 adjacent to the substrate 11.

In the present disclosure, the circuit layer 12 may further include a wire, a pad, a sensor, a driving circuit, other suitable components, or a combination thereof. The suitable component may include a passive component, an active component, or a combination thereof, such as a capacitor, a resistor, an inductor, a diode, a transistor, etc., but the present disclosure is not limited thereto. The diode may include a light emitting diode or a photodiode. The light emitting diode may include an organic light emitting diodes (OLED), a sub-millimeter light emitting diode (mini LED), a micro light emitting diode (micro LED) or a quantum dot (QD) light emitting diode (which may be, for example, QLED, QDLED) or other suitable materials or any arrangement and combination of the above materials, but the present disclosure is not limited thereto. In the present disclosure, the dimension of the electronic unit E in the circuit layer 12 is not particularly limited. The dimension of each electronic unit E may be adjusted as needed. For example, in FIG. 2A, the dimension of the electronic unit E in the middle may be greater than the dimension of the electronic unit E of the left or right side, but the present disclosure is not limited thereto. The “dimension of the electronic unit” refers, for example, to the maximum width or length of the electronic unit E in one direction (for example, the X direction).

Then, as shown in FIG. 1, FIG. 2B-1 and FIG. 2C, the manufacturing method of an electronic device may include: step (b), in which a plurality of cover plates 2 are respectively disposed on at least part of the electronic unit E, and a bonding material 3 is disposed on the first bonding member 13. One of the cover plates 2 includes a second bonding member 22. In the top view direction Z of the circuit substrate 1, the second bonding member 22 overlaps at least part of the first bonding member 13, and the bonding material 3 does not overlap the second bonding member 22.

In more detail, as shown in FIG. 2B-1 and FIG. 2B-2, FIG. 2B-2 is a top view of the cover plate 2, and the cover plate 2 may include a main body 21 and a second bonding member 22. The second bonding member 22 is disposed on one side 21s1 of the main body 21. The second bonding member 22 forms an annular structure adjacent to the edge of the main body 21. The edge of the annular structure is substantially aligned with the edge of the main body 21. The opening H2 surrounded by the annular structure exposes part of the side 21s1 of the main body 21, and the area of the opening H2 surrounded by the annular structure is substantially the same as the area of the opening H1 of the first bonding member 13. In the present disclosure, as shown in FIG. 2B-1, one cover plate 2 corresponds to one electronic unit E, and the area of the opening H1 of the first bonding member 13 is substantially equal to the area of the opening H2 of the second bonding member 22. The second bonding member 22 is disposed on one side 21s1 of the main body 21 facing the circuit substrate 1, so that the cover plate 2 and the circuit substrate 1 may be assembled using the first bonding member 13 and the second bonding member 22. In one embodiment of the present disclosure, in the top view direction Z of the circuit substrate 1, the projection area of the main body 21 of the cover plate 2 on the substrate 11 is greater than the projection area of the opening H of the first bonding member 13 on the substrate 11. Furthermore, as shown in FIG. 2C, in the top view direction Z of the circuit substrate 1, the first bonding member 13 has an overlapping area R1 overlapping the second bonding member 22, and the bonding material 3 is disposed on the first bonding member 13 outside the overlapping area R1, wherein the overlapping area R1 surrounds the electronic unit E in the top view direction Z.

In the present disclosure, the order in which the cover plate 2 and the bonding material 3 are disposed is not particularly limited. For example, in this embodiment, as shown in FIG. 2B and FIG. 2C, a plurality of cover plates 2 are first respectively disposed on at least part of the electronic unit E, and the bonding material 3 is then disposed on the first bonding member 13, but the present disclosure is not limited thereto. In other embodiments of the present disclosure, the bonding material 3 may first be disposed on the first bonding member 13, and then a plurality of cover plates 2 are respectively disposed on at least part of the electronic unit E.

In one embodiment of the present disclosure, in the top view direction Z of the circuit substrate 1, the bonding material 3 may be placed or formed between two adjacent electronic units E. In more detail, in the top view of the circuit substrate 1, as shown in FIG. 2C, the bonding material 3 may be placed or formed between two adjacent electronic units E, but the present disclosure is not limited thereto. In other embodiments of the present disclosure, although not shown in the figures, the bonding material 3 may be placed or formed on one side of the electronic unit E. For example, from a top view of the circuit substrate 1, the bonding material 3 may be placed or formed on the upper side of the electronic unit E, or the bonding material 3 may be placed or formed on the lower side of the electronic unit E, or the bonding material 3 may be placed or formed on the upper and lower sides of the electronic unit E, but the present disclosure is not limited thereto.

In the present disclosure, the material of the main body 21 may include silicon, germanium (Ge), zinc sulfide (ZnS), zinc selenide (ZnSe), gallium arsenide (GaAs), chalcogenide or a combination thereof, but the present disclosure is not limited thereto. In one embodiment of the disclosure, the main body 21 may be composed of, for example, a silicon substrate through which light of a specific wavelength (for example, light with a wavelength of 5 μm to 15 μm) may penetrate, but the present disclosure is not limited thereto. In the present disclosure, the second bonding member 22 may be made of the same or different materials as the first bonding member 13, and the material of the second bonding member 22 may be as described for the first bonding member 13, which will not be described again here. In the present disclosure, the thickness of the second bonding member 22 may be 0.1 μm to 500 μm, such as 50 μm to 500 μm, but the present disclosure is not limited thereto. In the present disclosure, the thickness of the second bonding member 22 may be greater than or equal to the thickness of the first bonding member 13.

In the present disclosure, the bonding material 3 may include solder material, tin solder, solder paste, or a combination thereof, but the present disclosure is not limited thereto. In the present disclosure, the bonding material 3 may include tin, tin alloy, or a combination thereof, but the present disclosure is not limited thereto. Since tin has a lower melting point, when the bonding material 3 contains tin, the temperature for melting the bonding material 3 subsequently may be reduced, thereby reducing damage to the circuit substrate 1 caused by excessively high temperature.

Then, as shown in FIG. 1 and FIG. 2D, the manufacturing method of an electronic device may include: step (c) in which the bonding material 3 is melted so that part of the bonding material 3 flows in between the first bonding member 13 and the second bonding member 22. More specifically, as shown in FIG. 2D, by heating the bonding material 3, the bonding material 3 may be melted into a liquid or semi-liquid state, and flows into the overlapping area R1 where the first bonding member 13 and the second bonding member 22 overlap, thereby the first bonding member 13 and the second bonding member 22 are bonded through the bonding material 3 to achieve the purpose of assembling the cover plate 2 and the circuit substrate 1. Therefore, a sealed space SP may be formed between the cover plate 2 and the circuit substrate 1, and the electronic unit E exists in the sealed space SP.

In the present disclosure, by heating and melting the bonding material 3, it is able to achieve the effect of assembling the cover plate 2 and the circuit substrate 1. Therefore, when the electronic device is manufactured by the manufacturing method of the present disclosure, it is able to reduce the bonding material 3 that overflows or is extruded into the sealed space SP between the cover plate 2 and the circuit substrate 1, thereby reducing the interference with the function (such as sensing sensitivity) of the electronic unit E and improving the yield of the electronic device. In addition, in other embodiments, other process conditions, such as pressure, may be added according to process requirements to assist the effect of assembling.

In one embodiment of the present disclosure, the temperature at which the bonding material 3 is heated may be greater than or equal to the melting temperature of the bonding material 3, for example, it may be 90° C. to 450° C., 150° C. to 450° C., or 200° C. to 400° C., but the present disclosure is not limited thereto. In the present disclosure, the “pressure” refers to the situation where a stress of greater than 0.1 MPa is applied during the process of melting the bonding material 3.

In the present disclosure, since the first bonding member 13 has affinity with the bonding material 3, when the bonding material 3 is melted, the bonding material 3 will flow along the position of the first bonding member 13. Therefore, as shown in FIG. 2D, in the top view direction Z of the circuit substrate 1, the bonding material 3 overlaps at least part of the first bonding member 13. In one embodiment of the present disclosure, the projection area of the bonding material 3 on the substrate 11 may be substantially equal to the projection area of the first bonding member 13 on the substrate 11. In one embodiment of the present disclosure, as shown in FIG. 2D, the bonding material 3 may include a first portion 31 and a second portion 32, wherein the first portion 31 is connected to the second portion 32, the first portion 31 is disposed between the first bonding member 13 and the second bonding member 22, and the second portion 32 is disposed on the first bonding member 13. In the top view direction Z of the circuit substrate 1, the second portion 32 does not overlap the second bonding member 22. In other words, the first portion 31 of the bonding material 3 is disposed within the overlapping area R1, and the second portion 32 of the bonding material 3 is disposed on the first bonding member 13 outside the overlapping area R1.

In one embodiment of the present disclosure, before step (c), the manufacturing may further includes a step of placing the circuit substrate 1 in a cavity (not shown) and vacuum-pumping the cavity. In the present disclosure, the aforementioned vacuum-pumping step may be performed at any stage before performing step (c). For example, after performing step (a), the circuit substrate 1 may be placed in the cavity and the cavity is vacuum-pumped, and then step (b) as well as subsequent steps may be performed. Alternatively, in step (b), after placing a plurality of cover plates 2 on at least part of the electronic unit E, the circuit substrate 1 is placed in the cavity and the cavity is vacuum-pumped, and then the subsequent steps such as placing the bonding material 3 on the first bonding member 13 may be performed. Alternatively, after performing step (a) and step (b), the circuit substrate 1 is placed in the cavity and the cavity is vacuum-pumped, and then the subsequent steps such as step (c) may be performed, but the present disclosure is not limited thereto. In the present disclosure, the “vacuum” refers to that the pressure in the cavity is, for example, less than or equal to 1 torr; for example, the pressure in the cavity may be 10⁻³ torr to 1 torr or 10⁻⁷ torr to 1 torr, but the present disclosure is not limited thereto. In the present disclosure, since a plurality of cover plates 2 are used to be assembled with one circuit substrate 1, during the vacuum-pumping step, it is not easy to cause inconsistent vacuum degree between the center and the edge of the circuit substrate 1, which can improve the vacuum effect within the sealed space SP.

Then, as shown in FIG. 1, FIG. 2E and FIG. 2F, the manufacturing method of an electronic device may include: step (d), in which the circuit substrate 1 and the bonding material 3 are cut to form a plurality of single units M. In more detail, the bonding material 3, the first bonding member 13, the circuit layer 12 and the substrate 11 may be cut respectively, for example, along the dotted lines in FIG. 2E, thereby forming single units M of appropriate dimension, as shown in FIG. 2F. In the present embodiment, as shown in FIG. 2E, the dotted line for cutting is substantially along the dimension of the circuit layer 12 of the single unit M. Therefore, as shown in FIG. 2F, the projection area of the circuit layer 12 in the single unit M may be substantially equal to the projection area of the substrate 11. However, in other embodiments of the present disclosure, the projection area of the substrate 11 in the single unit M may be greater than the projection area of the circuit layer 12. In the present disclosure, the method of cutting the circuit substrate 1 and the bonding material 3 may be performed, for example, by laser cutting, wheel knife cutting, or a combination thereof. In one embodiment of the present disclosure, the single unit M may be used as an electronic device or, in other embodiments, the electronic device may include a plurality of single units M, but the present disclosure is not limited thereto. In the present disclosure, the single unit M may have the function of receiving or transmitting signals, such as sensing temperature or emitting light, but the present disclosure is not limited thereto.

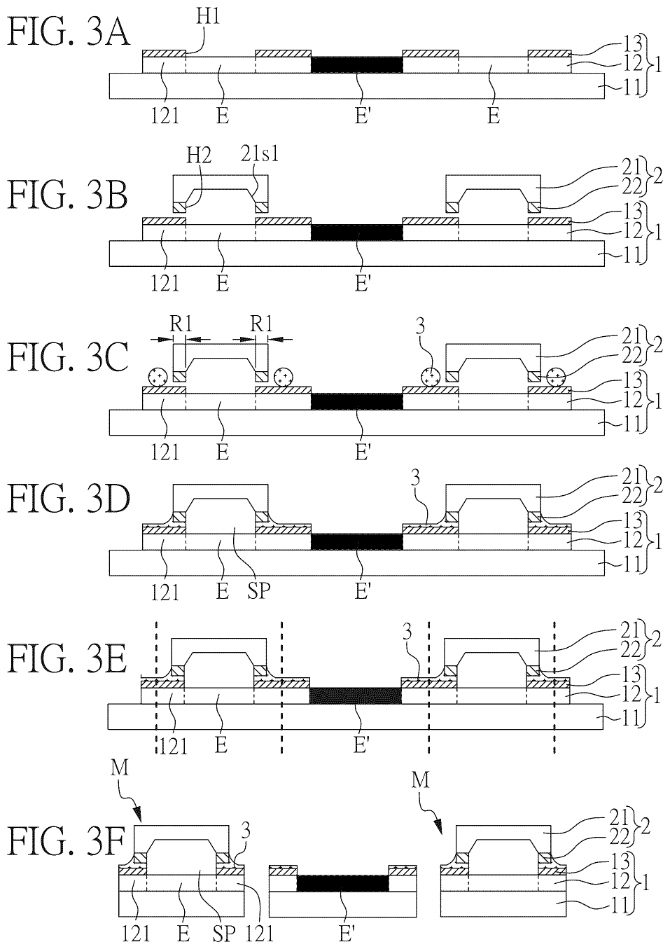

FIG. 3A to FIG. 3F are schematic diagrams illustrating a manufacturing method of an electronic device according to another embodiment of the present disclosure, wherein the manufacturing method of FIG. 3A to FIG. 3F is similar to the manufacturing method of FIG. 2A to FIG. 2F except for the following differences.

In one embodiment of the present disclosure, as shown in FIG. 3A, the manufacturing method of an electronic device may include: step (a), in which a circuit substrate 1 is provided. The details of the circuit substrate 1 may be as described above and will not be described again here. Next, as shown in FIG. 3B and FIG. 3C, the manufacturing method of an electronic device may include: step (b), in which a plurality of cover plates 2 are respectively disposed on at least part of the electronic unit E, and a bonding material 3 is disposed on the first bonding member 13. In more detail, step (b) includes: detecting the electronic units E on the circuit substrate 1 and determining whether the electronic units E are normal or abnormal (i.e., defective); and respectively disposing cover plates 2 on the normal electronic units E and not disposing cover plates 2 on the defective electronic units E′. The details of the cover plate 2 and the bonding material 3 are as described above and will not be described again here. The defective electronic unit E′ is represented by a black-filled pattern in the figures. In this embodiment, in FIG. 3A, two normal electronic units E and one abnormal electronic unit E′ are taken as an example, but the present disclosure is not limited thereto.

In one embodiment of the present disclosure, the electronic unit E may be detected first to determine whether the electronic unit E is normal or defective, and then the cover plate 2 is disposed on the normal electronic unit E, so as to reduce the waste of the cover plate 2 thereby achieving the effect of reducing manufacturing costs. In the present disclosure, the “normal electronic unit” refers, for example, to that the electronic unit E has normal appearance, abnormal electrical properties, etc., and the electronic unit E may be operated. The “abnormal electronic unit” refers, for example, to that the electronic unit E′ has abnormal appearance, abnormal electrical properties, or a combination thereof. In the present disclosure, detecting the electronic unit E includes performing electrical testing, electrostatic discharge testing, appearance testing, other suitable testing, or a combination thereof on the electronic unit E, but the present disclosure is not limited thereto.

Then, as shown in FIG. 3D, the manufacturing method of an electronic device may include: step (c), in which the bonding material 3 is melted so that part of the bonding material 3 flows in between the first bonding member 13 and the second bonding member 22. The details of the step of melting the bonding material 3 may be as described above and will not be described again here.

In one embodiment of the present disclosure, before step (c), the manufacturing method may further includes a step of placing the circuit substrate 1 in a cavity (not shown) and vacuum-pumping the cavity. In the present disclosure, the aforementioned vacuum-pumping step may be performed at any stage before performing step (c). For example, after performing step (a), the circuit substrate 1 may be placed in the cavity and the cavity is vacuum-pumped, and then the subsequent steps such as step (b) may be performed. Alternatively, in step (b), after detecting the electronic unit E on the circuit substrate 1 and making a determination, the circuit substrate 1 is placed in the cavity and the cavity is vacuum-pumped, and then cover plates 2 are respectively disposed on the normal electronic unit E, and no cover plates 2 are disposed on the defective electronic units E′, and then the subsequent steps such as disposing the bonding material 3 on the first bonding member 13 are performed. Alternatively, in step (b), after the cover plates 2 are respectively disposed on the normal electronic unit E′ and no cover plates 2 are disposed on the defective electronic units E′, the circuit substrate 1 is placed in the cavity and the cavity is vacuum-pumped, and then the subsequent steps such as disposing the bonding material 2 on the first bonding member 13 are performed. Alternatively, after performing step (a) and step (b), the circuit substrate 1 may be placed in the cavity and the cavity may be vacuum-pumped, and then subsequent steps such as step (c) may be performed, but the present disclosure is not limited thereto. In the present disclosure, the “vacuum” refers to that the pressure in the cavity is, for example, less than or equal to 1 torr; for example, the pressure in the cavity may be 10⁻³ torr to 1 torr or 10⁻⁷ torr to 1 torr, but the present disclosure is not limited thereto.

Then, as shown in FIG. 3E and FIG. 3F, the manufacturing method of an electronic device may include: step (d), in which the circuit substrate 1 and the bonding material 3 are cut to form a plurality of single units M. The details of the cutting step may be as described above and will not be described again here. In one embodiment of the present disclosure, as shown in FIG. 3F, since there is no need to assemble the cover plate 2 for the abnormal electronic unit E′, the effect of cost reduction can be achieved.

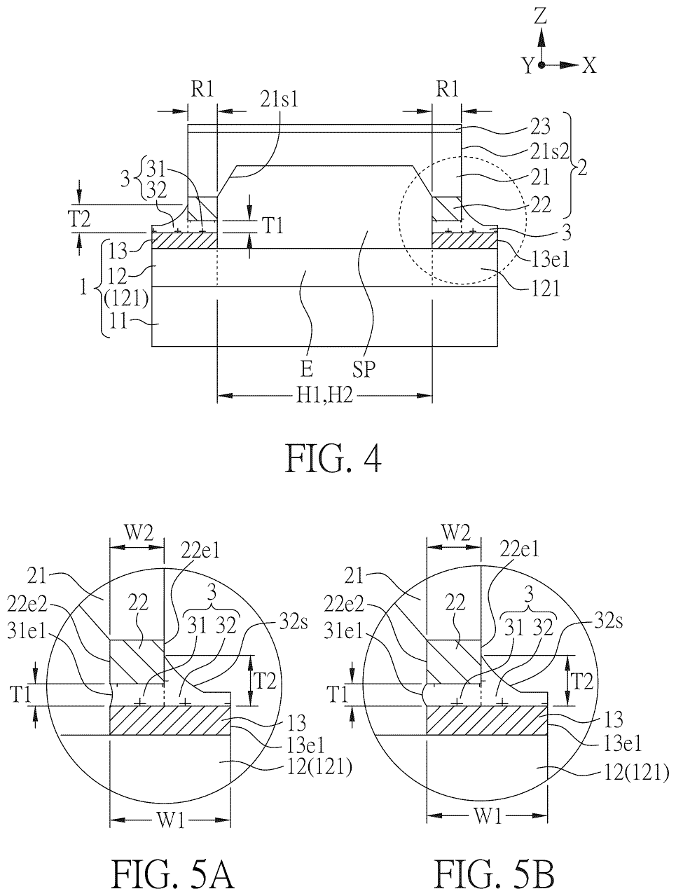

The electronic device prepared by the above manufacturing method may be shown in FIG. 4 to FIG. 5B, which will be described in detail below.

FIG. 4 is a schematic cross-sectional view of an electronic device according to an embodiment of the present disclosure, and FIG. 5A and FIG. 5B are enlarged schematic diagrams of part of an electronic device according to an embodiment of the present disclosure, wherein FIG. 5A and FIG. 5B are respectively enlarged views of the dotted line in FIG. 4.

In one embodiment of the present disclosure, as shown in FIG. 4, the electronic device includes: a circuit substrate 1 having a substrate 11; an electronic unit E disposed on the substrate 11; and a first bonding member 13 disposed on the substrate 11 and surrounding the electronic unit E; a cover plate 2 disposed on the first bonding member 13, wherein the cover plate 2 has a second bonding member 22 and, in the top view direction Z of the circuit substrate 1, the cover plate 2 overlaps the electronic unit E, and the second bonding member 22 overlaps at least part of the first bonding member 13; and a bonding material 3 including a first portion 31 and a second portion 32, wherein the first portion 31 is disposed between a first bonding member 13 and a second bonding member 22, and the second portion 32 is disposed on the first bonding member 13. In the top view direction Z of the circuit substrate 1, the second portion 32 does not overlap the second bonding member 22. The thickness of the first portion 31 of the bonding material 3 (that is, the first thickness T1) is smaller than the thickness of the second portion 32 (that is, the second thickness T2).

In more detail, the circuit substrate 1 may include a circuit layer 12 disposed on the substrate 11. The circuit layer 12 may include electronic units E, wherein the first bonding 13 is disposed on the circuit layer 12, and the first bonding member 13 may be disposed around the electronic unit E in the top view direction Z of the circuit substrate 1. The first bonding member 13 may include an opening H and, in the top view direction Z of the circuit substrate 1, the opening H of the first bonding member 13 corresponds to the electronic unit E. In one embodiment of the present disclosure, in the top view direction Z of the circuit substrate 1, the projection area of the opening H of the first bonding member 13 on the substrate 11 may be substantially equal to the projection area of the electronic unit E on the substrate 11. In the present disclosure, the cover plate 2 may include a main body 21 and a second bonding member 22. The second bonding member 22 is disposed on the main body 21, wherein the second bonding member 22 is disposed on one side of the main body 21 facing the circuit substrate 1. In other words, the second bonding member 22 is closer to the circuit substrate 1 than the main body 21. The first bonding member 13 and the second bonding member 22 may be bonded through the bonding material 3, so that a sealed space SP is formed between the cover plate 2 and the electronic unit E.

In the present disclosure, as shown in FIG. 4 to FIG. 5B, in one direction (for example, X direction), the first bonding member 13 has a first width W1, and the second bonding member 22 has a second width W2, wherein the first width W1 is greater than the second width W2. In the present disclosure, as shown in FIG. 4, in the top view direction Z of the circuit substrate 1, the first bonding member 13 has an overlapping area R1 overlapping the second bonding member 22. More specifically, the first portion 31 of the bonding material 3 is disposed in the overlapping area R1, and the second portion 32 of the bonding material 3 is disposed on the first bonding member 13 outside the overlapping area R1. In the present disclosure, the first portion 31 of the bonding material 3 has a first thickness T1, and the second portion 32 of the bonding material 3 has a second thickness T2, wherein the first thickness T1 is smaller than the second thickness T2. In one embodiment of the present disclosure, the second thickness T2 may be 50 μm to 500 μm. When the first thickness T1 and the second thickness T2 satisfy the above design, the bonding material 3 may provide an excellent bonding effect and prevent undesired substances (such as moisture, air, dust or a combination thereof) from entering the sealed space SP.

In the present disclosure, the “first width” refers, for example, to the maximum distance from an edge 13e1 of the first bonding member 13 to the opening H in one direction (for example, X direction). The “second width” refers, for example, to the maximum distance from one edge 22e1 to the other edge 22e2 of the second bonding member 22 in one direction (for example, X direction), wherein the edge 22e1 of the second bonding member 22 is further away from the opening H than the other edge 22e2. In the present disclosure, the “first thickness T1” refers, for example, to the maximum dimension of the first portion 31 of the bonding material 3 in the top view direction Z of the circuit substrate 1, or refers, for example, to the maximum height of the bonding material 3 between the first bonding member 13 and the second bonding member 22 in the overlapping area R1. The “second thickness” refers, for example, to the maximum dimension of the second portion 32 of the bonding material 3 in the top view direction Z of the circuit substrate 1. Alternatively, because the second portion 32 of the bonding material 3 may have an uneven surface 32s, the second thickness T2 refers to, for example, in a cross-section, in the direction perpendicular to the substrate 11 (for example, Z direction), the distance between the portion of the surface 32s of the second portion 32 that is farthest away from the first bonding member 13 and the surface of the first bonding member 13. In one embodiment of the present disclosure, due to the affinity between the bonding material 3 and the second bonding member 22, the second portion 32 of the bonding material 3 may be in contact with the edge 22e1 of the second bonding member 22.

In one embodiment of the present disclosure, as shown in FIG. 5A, the first portion 31 of the bonding material 3 may have a recess portion, and the second portion 32 of the bonding material 3 may have an arc surface. The “recess portion” refers, for example, to an edge 31e1 of the first portion 31 of the bonding material 3 being recessed or close to the second portion 32 of the bonding material 3. The “arc surface” refers, for example, to the surface 32s of the second portion 32 of the bonding material 3 being an uneven surface.

In another embodiment of the present disclosure, as shown in FIG. 5B, the first portion 31 of the bonding material 3 may have a protrusion portion, and the second portion 32 of the bonding material 3 may have an arc surface. The “protrusion portion” refers, for example, to an edge 31e1 of the first portion 31 of the bonding material 3 protruding toward a direction away from the second portion 32 of the bonding material 3. The “arc surface” refers, for example, to the surface 32s of the second portion 32 of the bonding material 3 being an uneven surface.

In one embodiment of the present disclosure, as shown in FIG. 4, the cover plate 2 may further include an anti-reflection layer 23 disposed on the main body 21. More specifically, the cover plate 2 includes the main body 21, the second bonding member 22 and the anti-reflection layer 23, wherein the second bonding member 22 is disposed on one side of the main body 21 facing the circuit substrate 1, and the anti-reflection layer 23 is disposed on one side of the main body 21 away from the circuit substrate 1. In other words, the main body 21 of the cover plate 2 is disposed between the second bonding member 22 and the anti-reflection layer 23. In one embodiment of the present disclosure, the anti-reflection layer 23 may be disposed on one side of the main body 21 away from the circuit substrate 1. In another embodiment (not shown), the anti-reflection layer 23 may be disposed on one side of the main body 21 away from the circuit substrate 1 and the side wall 21s2 of the main body 21 of the cover plate 2, but it is not limited thereto. The anti-reflection layer 23 may be used to reduce reflection of light in a specified wavelength range and/or block the entry of light outside the specified wavelength range, so as to increase the transmittance of light in the specified wavelength range. In one embodiment of the present disclosure, the light within the specified wavelength range is, for example, light with a wavelength of 5 μm to 15 μm, but the present disclosure is not limited thereto.

In one embodiment of the present disclosure, the material of the anti-reflection layer 23 may include silicon, germanium (Ge), zinc sulfide (ZnS), zinc selenide (ZnSe), magnesium fluoride (MgF₂), beryllium fluoride (BeF₂), potassium chloride, arsenic trisulfide (As₂S₃), silicon oxide, silicon nitride, silicon oxynitride, indium tin oxide (ITO), aluminum zinc oxide (AZO), oxide Indium gallium zinc oxide (IGZO), antimony tin oxide (ATO), fluorine-doped tin oxide (FTO) or a combination thereof, but the present disclosure is not limited thereto. In one embodiment of the present disclosure, the anti-reflection layer 23 may include a plurality of high refractive index layers and a plurality of low refractive index layers, wherein the high refractive index layers and the low refractive index layers are alternately stacked with each other. Through the stacked design of film layers with different refractive indexes, the anti-reflection layer 23 may achieve the effect of reducing reflected light. The “high refractive index layer” refers, for example, to a film layer made of a material with a refractive index greater than or equal to 1.38 and less than or equal to 1.48. The “low refractive index layer” refers, for example, to a film layer made of a material with a refractive index greater than or equal to 1.8 and less than or equal to 2.1.

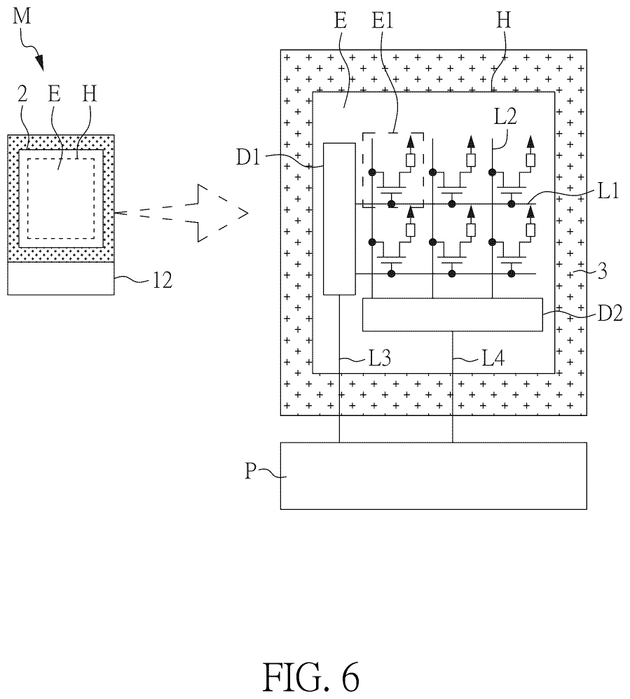

FIG. 6 is a schematic diagram of an electronic unit according to an embodiment of the present disclosure, wherein the right side of FIG. 6 is a partially enlarged view of the left side and, for convenience of explanation, some components, such as the substrate 11 and the cover plate 2, are omitted in the right side of the figure.

In one embodiment of the present disclosure, as shown in FIG. 6, the electronic unit E may include a plurality of electronic components E1; a first driver D1; and a second driver D2, wherein the first driver D1 and the second driver D2 are electrically connected to the plurality of electronic components E1, respectively. In more detail, the first driver D1 and the second driver E2 may be electrically connected to each electronic component E1 through a first conductive wire L1 and a second conductive wire L2, respectively, so as to transmit or receive signals. For example, the first driver D1 may transmit control signals through the first conductive wire L1 to control the electronic component E1, or the second driver D2 may receive signals generated by the electronic component E1 through the second conductive wire L2, but the present disclosure is not limited thereto. In the present disclosure, the electronic component E1 may include a plurality of transistors, wherein the transistors may further include semiconductors, gates, sources, and drains. In addition, the electronic component E1 may also include one or more sensing units (not shown), such as a sensor or a material structure that may absorb light wavelengths, in which a plurality of transistors may be electrically connected to one or more sensing units, but the present disclosure is not limited thereto. In addition, the components in the electronic unit E may be manufactured through the same or different process methods, such as thin film technology, or the use of bonding to integrate the required components.

In one embodiment of the present disclosure, as shown in FIG. 6, the electronic device may further include a component P, which is electrically connected to the first driver D1 (for example, a gate driver) and the second driver D2 (for example, a data control), respectively. The first driver D1 and the second driver D2 may be manufactured by thin film process, photolithography or etching, but it is not limited thereto. More specifically, the component P may be electrically connected to the first driver D1 through the conductive wire L3, and may be electrically connected to the second driver D2 through the conductive wire L4, and may be used, for example, to control or process signals transmitted to the first driver D1 or received from the second driver D2. In one embodiment of the present disclosure, the component P may be an integrated circuit (IC), but the present disclosure is not limited thereto. In addition, although the first driver D1 and second driver D2 are taken as an example in FIG. 6, in other embodiments of the present disclosure, the electronic unit E may include a plurality of first drivers D1 and/or a plurality of second drivers D2, which may be electrically connected to the component P through a plurality of conductive wires L3 and/or conductive wires L4, respectively.

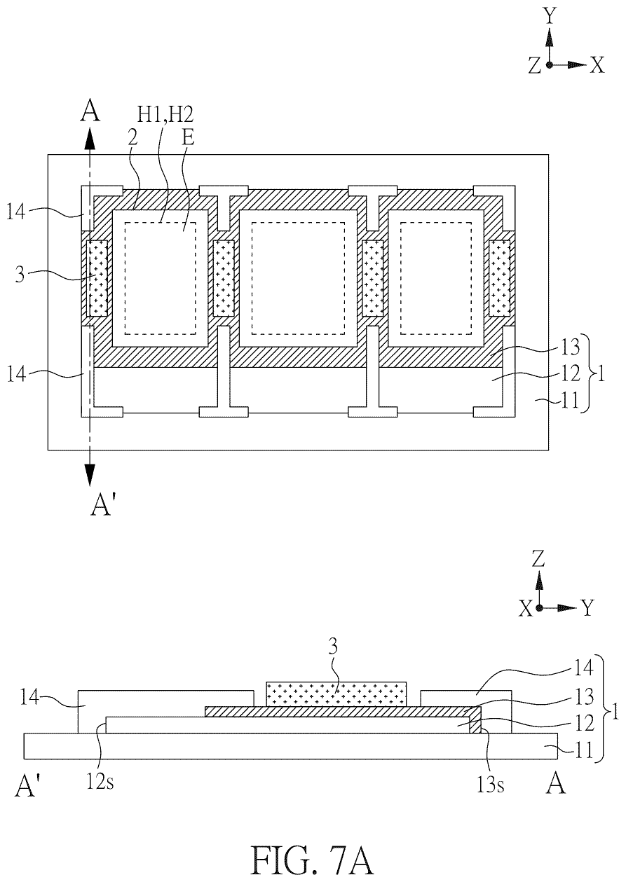

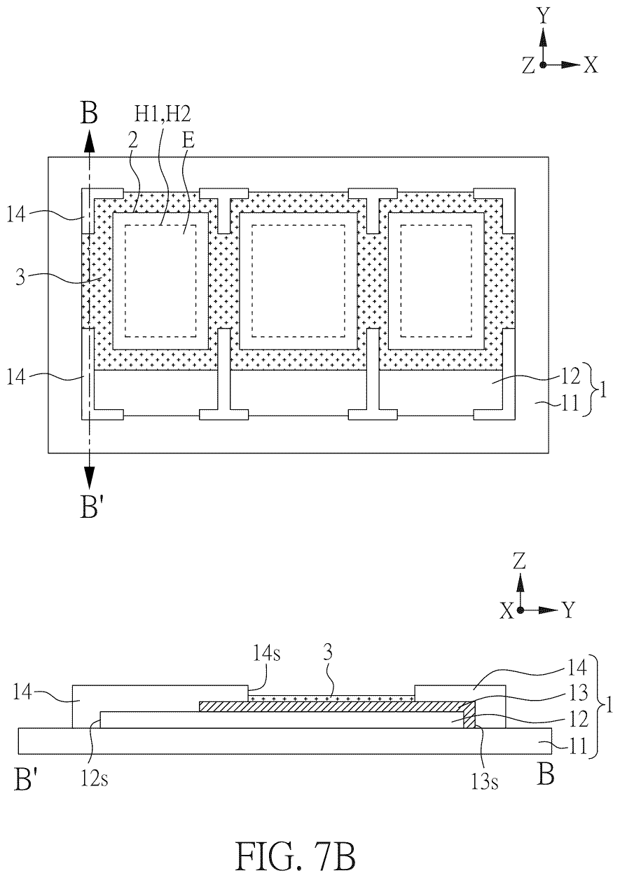

FIG. 7A and FIG. 7B are schematic diagrams illustrating a manufacturing method of an electronic device according to an embodiment of the present disclosure, wherein the upper half portions of FIG. 7A and FIG. 7B are schematic top views, and the lower half portions are schematic cross-sectional views. For convenience of explanation, some components are omitted from the schematic views. The manufacturing method of FIG. 7A and FIG. 7B is similar to that of FIG. 2C and FIG. 2D except for the following differences.

In one embodiment of the present disclosure, as shown in FIG. 7A and FIG. 7B, the circuit substrate 1 may further include a limiting member 14 disposed on the first bonding member 13, wherein, in a top view direction Z of the circuit substrate 1, the limiting member 14 is disposed around the electronic unit E. In more detail, the limiting member 14 is disposed on the substrate 11, the circuit layer 12 and the first bonding member 13, and the limiting member 14 may cover part of the circuit layer 12 and the first bonding member 13. In one embodiment of the present disclosure, in a cross-sectional view, the limiting member 14 may be in contact with the side wall 12s of the circuit layer 12 and/or the side wall 13s of the first bonding member 13.

In the present disclosure, the material of the limiting member 14 may include organic materials, and suitable organic materials include polycarbonate (PC), polyimide (PI), polypropylene (PP), polyethylene terephthalate (PET), polybenzoxazole (PBO), benzocyclobutene (ECB), perfluoroalkoxy (PFA), cyclic oxygen resin, photoresist, polymer or a combination thereof, but the present disclosure is not limited thereto.

In one embodiment of the present disclosure, after performing step (a) and step (b), as shown in FIG. 7A, in the top view direction Z of the circuit substrate 1, the cover plate 2 and the limiting member 14 do not overlap, and the bonding material 3 and the limiting member 14 do not overlap. The limiting member 14 may be used to position the relative position of the cover plate 2 and/or the bonding material 3 and the circuit substrate 1 so as to reduce the displacement caused by external forces when the circuit substrate 1 and the cover plate 2 are assembled, thereby reducing assembly tolerances or errors. In the present disclosure, the details of the circuit substrate 1, the cover plate 2 and the bonding material 3 may be as described above and will not be described again.

After that, step (c) is performed to melt the bonding material 3. As shown in FIG. 7B, the bonding material 3 is disposed between the limiting members 14. In one embodiment of the present disclosure, as shown in FIG. 7B, the bonding material 3 may be in contact with the side wall 14s of the limiting member 14. Then, although not shown in the figure, reference may be made to FIG. 2E and FIG. 2F, and step (d) is performed on the electronic device to cut the circuit substrate 1 and the bonding material 3 so as to form single units. The details of the cutting step may be as described above and will not be described again here. Therefore, in one embodiment of the present disclosure, the electronic device may include the limiting member 14 disposed on the first bonding member 13. In one embodiment of the present disclosure, step (d) may optionally include cutting the limiting member 14.

In addition, in one embodiment of the present disclosure, step (b) may include: detecting the electronic units E on the circuit substrate 1, and determining whether the electronic units E are normal or defective; and disposing cover plates 2 on the normal electronic units E, and not disposing cover plates 2 on the defective electronic units E′. The details of the above step of detecting the electronic units E may be as described above and will not be described again here.

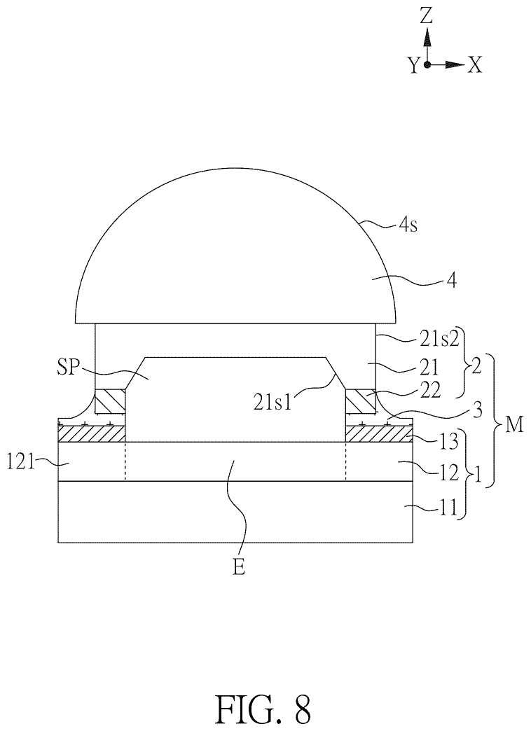

FIG. 8 is a schematic cross-sectional view of an electronic device according to an embodiment of the present disclosure, wherein the electronic device shown in FIG. 8 is similar to that of FIG. 4 except for the following differences.

In one embodiment of the present disclosure, the manufacturing method of an electronic device may further include a step of disposing a lens 4 on the single unit M. Therefore, as shown in FIG. 8, the electronic device may include a lens 4 disposed on the cover plate 2. In more detail, the lens 4 is disposed on one side of the main body 21 of the cover plate 2 away from the circuit substrate 1. The lens 4 may allow light in a specific wavelength range to penetrate through for focusing, so as to increase the transmittance of light in a specific wavelength range. In one embodiment of the present disclosure, the electronic device may also include an anti-reflection layer 23 (as shown in FIG. 4), which is disposed on one side 4s of the lens 4 away from the cover plate 2. Alternatively, in other embodiments, with reference to FIG. 8, the anti-reflection layer 23 (shown in FIG. 4) may be disposed on one side 4s of the lens 4 away from the cover plate 2 and the side wall 21s2 of the main body 21 of the cover plate 2.

In the present disclosure, the material of the lens 4 may include silicon, germanium (Ge), chalcogenide glass, gallium arsenide (GaAs), zinc sulfide (ZnS), zinc selenide (ZnSe) or a combination thereof, but the present disclosure is not limited thereto. In the present disclosure, other details of the circuit substrate 1, the cover plate 2 and the bonding material 3 may be as described above and will not be described again.

By disposing the first bonding member 13, the second bonding member 22 and the bonding material 3 and using the manufacturing method of the present disclosure, it is able to reduce the overflow or extrusion of the bonding material 3 to the sealed space SP between the cover plate 2 and the circuit substrate 1, thereby improving the yield of the electronic device. In addition, in the present disclosure, the vacuum effect in the sealed space SP may be improved or the manufacturing cost may be reduced by assembling a plurality of cover plates 2 and one circuit substrate 1.

The aforementioned specific embodiments should be construed as merely illustrative, and not limiting the rest of the present disclosure in any way.

1. A manufacturing method of an electronic device, comprising the steps of:
(a) providing a circuit substrate including: a substrate; a plurality of electronic units disposed on the substrate; and a first bonding member disposed on the substrate, wherein, in a top view direction of the circuit substrate, the first bonding member surrounds the electronic units;
(b) respectively disposing a plurality of cover plates on at least part of the electronic units, and disposing a bonding material on the first bonding member, wherein one of the cover plates includes a second bonding member and, in the top view direction of the circuit substrate, the second bonding member overlaps at least part of the first bonding member, and the bonding material does not overlap the second bonding member; and
(c) melting the bonding material to allow part of the bonding material to flow in between the first bonding member and the second bonding member.

2. The manufacturing method as claimed in claim 1, further comprising the step of: cutting the circuit substrate and the bonding material to form a plurality of single units.

3. The manufacturing method as claimed in claim 2, further comprising the step of: disposing a plurality of lenses on the single units, respectively.

4. The manufacturing method as claimed in claim 1, wherein step (b) includes:
detecting the electronic units on the circuit substrate and determining whether the electronic units are normal or defective; and
respectively disposing the cover plates on the normal electronic units, and not disposing the cover plates on the defective electronic units.

5. The manufacturing method as claimed in claim 1, further comprising before step (c), the step of placing the circuit substrate in a cavity and vacuum-pumping the cavity.

6. The manufacturing method as claimed in claim 1, wherein, in the top view direction of the circuit substrate, the bonding material is formed between two adjacent electronic units.

7. The manufacturing method as claimed in claim 1, wherein the first bonding member includes a plurality of first openings, which respectively expose the plurality of electronic units.

8. The manufacturing method as claimed in claim 1, wherein the first bonding member has a thickness of 0.1 μm to 500 μm.

9. The manufacturing method as claimed in claim 7, wherein the cover plate further includes a main body, the second bonding member is disposed on one side of the main body, an edge of the second bonding member adjacent to the main body forms an annular structure, an edge of the annular structure is aligned with an edge of the main body, and a second opening surrounded by the annular structure exposes part of the side of the main body.

10. The manufacturing method as claimed in claim 9, wherein an area of the first opening of the first bonding member is equal to an area of the second opening of the second bonding member.

11. The manufacturing method as claimed in claim 1, wherein the second bonding member has a thickness of 0.1 μm to 500 μm, and the thickness of the second bonding member is greater than or equal to a thickness of the first bonding member.

12. An electronic device, comprising:
a circuit substrate including:
a substrate;
an electronic unit disposed on the substrate; and
a first bonding member disposed on the substrate and surrounding the electronic unit;
a cover plate disposed on the first bonding member, wherein the cover plate includes a second bonding member and, in a top view direction of the circuit substrate, the cover plate overlaps the electronic unit, and the second bonding member overlaps at least part of the first bonding member; and
a bonding material including a first portion and a second portion, the first portion being disposed between the first bonding member and the second bonding member, the second portion being disposed on the first bonding member, wherein, in the top view direction of the circuit substrate, the second portion does not overlap the second bonding member,
wherein a thickness of the first portion is smaller than a thickness of the second portion of the bonding material.

13. The electronic device as claimed in claim 12, wherein the circuit substrate further includes a limiting member disposed on the first bonding member and, in the top view direction of the circuit substrate, the limiting member is disposed around the electronic unit.

14. The electronic device as claimed in claim 12, wherein a thickness of the second portion of the bonding material is between 50 μm and 500 μm.

15. The electronic device as claimed in claim 12, wherein, in a cross-sectional view, a width of the first bonding member is greater than a width of the second bonding member.

16. The electronic device as claimed in claim 12, wherein the bonding material contains solder material.

17. The electronic device according to claim 12, wherein a material of the first bonding member includes aluminum, nickel, gold, palladium, copper, titanium, alloy thereof or a combination thereof.

18. The electronic device as claimed in claim 12, wherein the cover plate includes a main body and an anti-reflection layer, and the anti-reflection layer is disposed on the main body.

19. The electronic device as claimed in claim 18, wherein a material of the main body includes silicon, germanium, zinc sulfide, zinc selenide, gallium arsenide, chalcogenide or a combination thereof.

20. The electronic device as claimed in claim 18, wherein the anti-reflection layer includes a plurality of layers of first refractive index and a plurality of layers of second refractive index, wherein the layers of first refractive index and the layers of second refractive index are stacked alternately with each other, and the first refractive index is higher than the second refractive index.
